(19) United States
(12) Patent Application Publication
(10) Pub. No.: US 2024/0379759 A1
(43) Pub. Date: Nov. 14, 2024

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Wei-Yip LOH, Hsinchu City (TW); Li-Wei CHU, New Taipei City (TW); Hong-Mao LEE, Hsinchu City (TW); Hung-Chang HSU, Kaohsiung City (TW); Hung-Hsu CHEN, Tainan City (TW); Harry CHIEN, Chandler, AZ (US); Chih-Wei CHANG, Hsinchu County (TW)

(73) Assignee: TAIWAN SEMICONDUCTOR MANUFACTURING COMPANY, LTD., Hsinchu (TW)

(21) Appl. No.: 18/314,968

(22) Filed: May 10, 2023

(51) Int. Cl. H01L 29/08; H01L 21/8238; H01L 27/092; H01L 29/06; H01L 29/423; H01L 29/66; H01L 29/775; H01L 29/786

(52) U.S. Cl. CPC H01L 29/0847; H01L 21/823807; H01L 21/823814; H01L 21/823878; H01L 27/092; H01L 29/0673; H01L 29/42392; H01L 29/66545; H01L 29/775; H01L 29/78696

(57) ABSTRACT

A semiconductor device includes a first transistor, a second transistor, a first metal silicide layer, a second metal silicide layer, and an isolation structure. The first transistor includes a first channel layer, a first gate structure, and first source/drain epitaxy structures. The second transistor includes a second channel layer, a second gate structure, and second source/drain epitaxy structures. The first metal silicide layer is over one of the first source/drain epitaxy structures. The second metal silicide layer is over one of the second source/drain epitaxy structures. The isolation structure covers the one of the first source/drain epitaxy structures and the one of the second source/drain epitaxy structures, wherein in a cross-sectional view, the one of the first source/drain epitaxy structures is separated from the isolation structure through the first metal silicide layer, while the one of the second source/drain epitaxy structures is in contact with the isolation structure.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 19B illustrate a method in various stages of forming a power amplifier in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

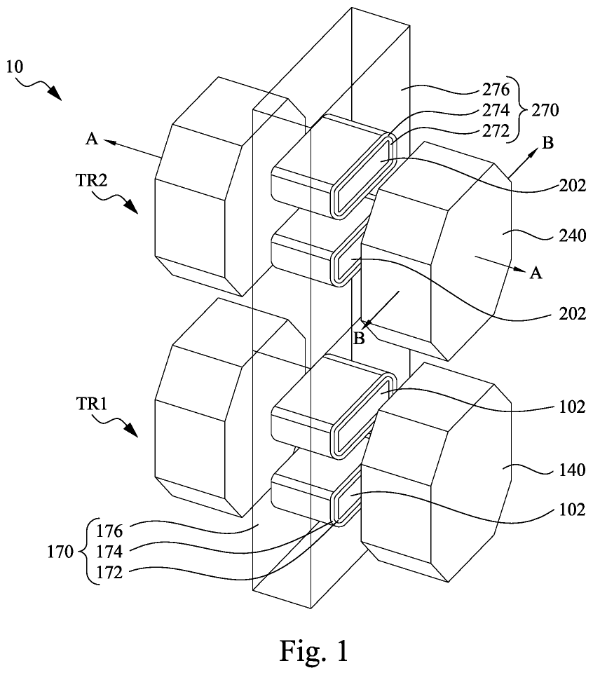

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FET. The first transistor TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, the second transistor TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, the first transistor TR1 has a first conductivity type (e.g., p-type) and the second transistor TR2 has a second conductivity type (e.g., n-type) different from the first conductivity type. In some embodiments, the first transistor TR1 can be referred to as a P-FET, and the second transistor TR2 can be referred to as an N-FET.

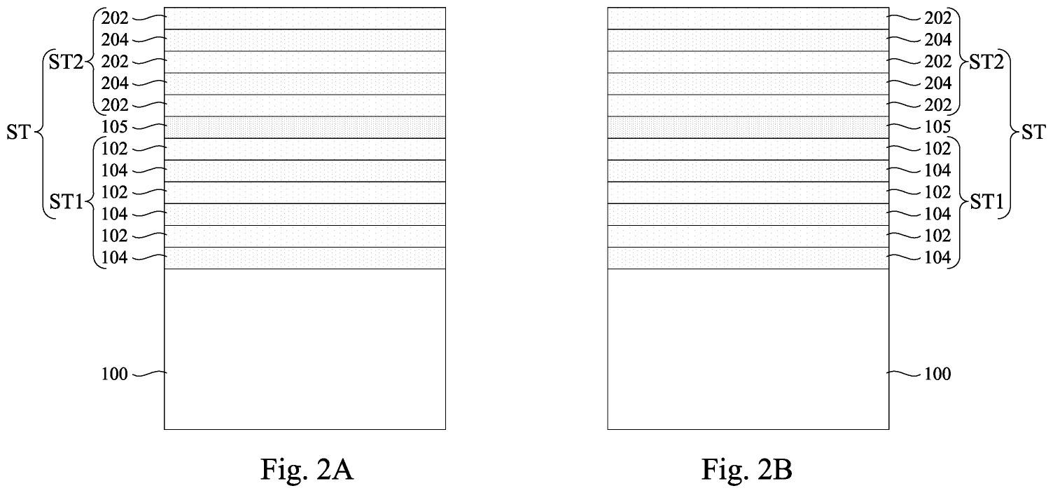

FIGS. 2A to 19B illustrate a method in various stages of forming a power amplifier in accordance with some embodiments of the present disclosure. It is noted that FIGS. 2A, 3A, 4A, 5A, 6A, 7A, 8A, 9A, 10A, 11A, 12A, 13A, 14A, 15A, 16A, 17A, 18A, and 19A include cross-sectional views the same as the cross-sectional view along line A-A of FIG. 1, and FIGS. 2B, 3B, 4B, 5B, 6B, 7B, 8B, 9B, 10B, 11B, 12B, 13B, 14B, 15B, 16B, 17B, 18B, and 19B include cross-sectional views the same as the cross-sectional view along line B-B of FIG. 1. Although FIGS. 2A to 19B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 19B may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers.

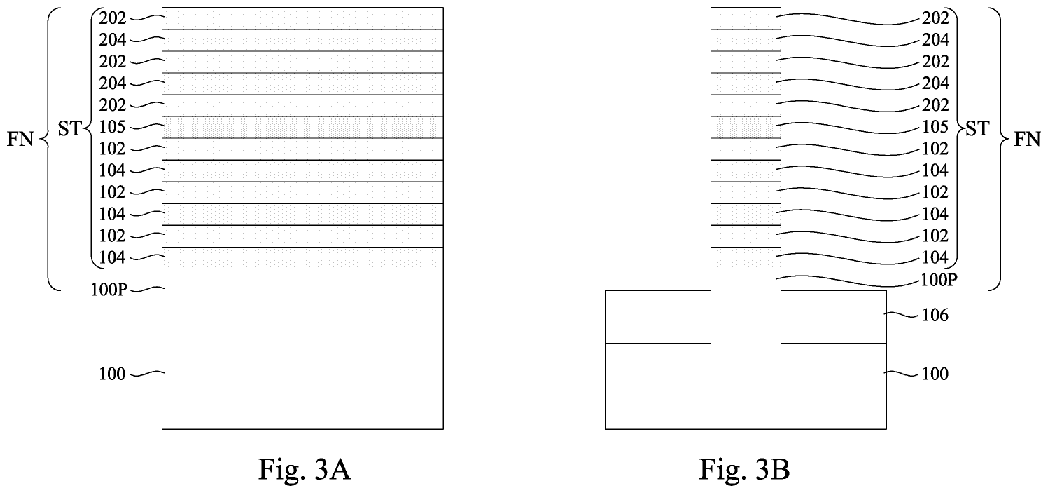

Reference is made to FIGS. 3A and 3B. A patterning process is performed to the semiconductor stack ST and the substrate 100 to form a fin structure FN. In some embodiments, the patterning process may include forming a patterned photoresist layer over the stack ST, and then performing an etching process to remove unwanted portions of the semiconductor stack ST and the substrate 100 exposed by the patterned photoresist layer. The fin structure FN may include a remaining portion of the semiconductor stack ST and a semiconductor strip 100P protruding over the substrate 100. In some embodiments, the etching process may include wet etch, dry etch, or the like.

After the fin structure FN is formed, isolation structures 106 are formed over the substrate 100 and laterally surrounding the fin structure FN. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

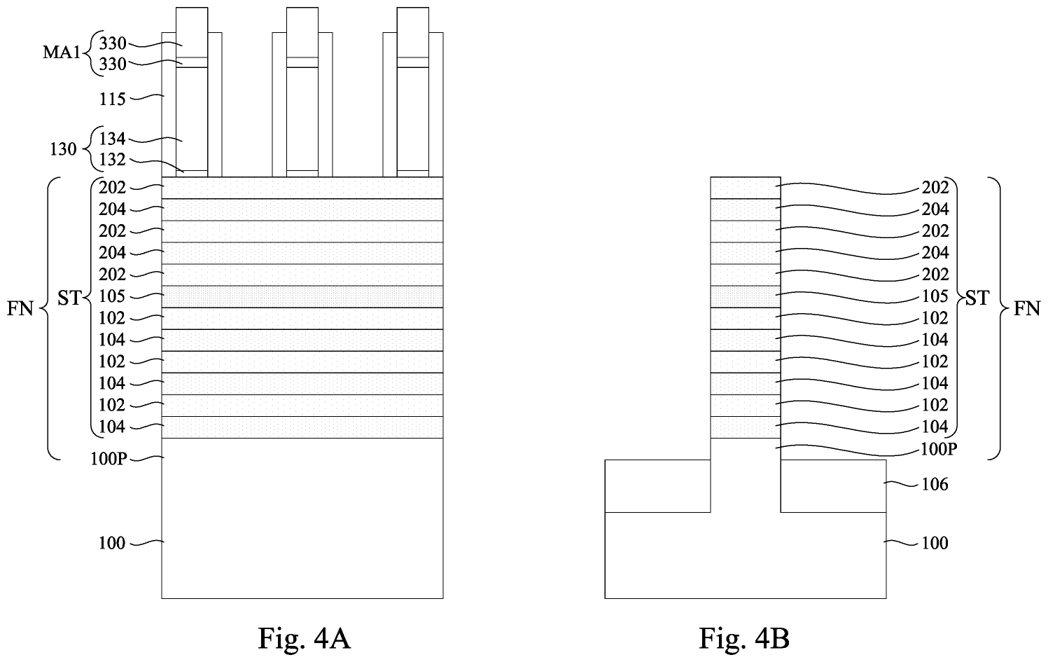

Reference is made to FIGS. 4A and 4B. Dummy gate structures 130 are formed over the substrate 100 and crossing the fin structure FN. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Gate spacers 115 are formed on opposite sidewalls of each of the dummy gate structures 130. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130. In some embodiments, the remaining vertical portions of the spacer layer on sidewalls of the dummy gate structures 130 can be referred to as gate spacers 115. In some embodiments, the spacer layer may be deposited using techniques such CVD, ALD, or the like.

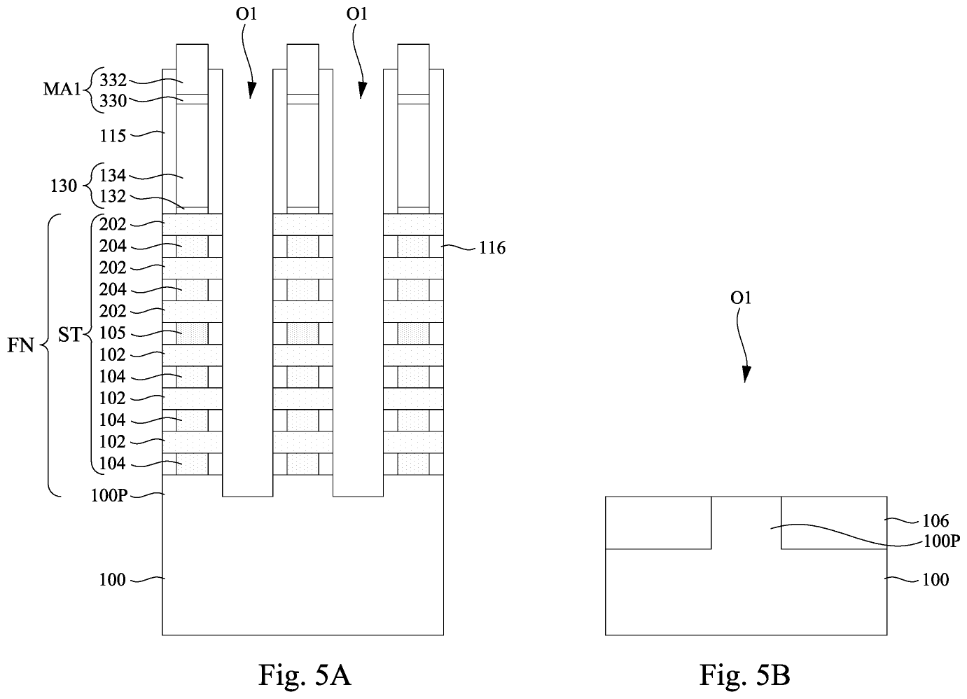

Reference is made to FIGS. 5A and 5B. An etching process is performed to remove portions of the fin structure FN (or semiconductor stack ST) by using the dummy gate structures 130 and the gate spacers 115 as etch mask, so as to form source/drain openings O1 in the fin structure FN (or in the semiconductor stack ST). In some embodiments, the etching process may be wet etch, dry etch, or combinations thereof.

After the source/drain openings O1 are formed, the semiconductor layers 104, 105, and 204 are laterally etched to form sidewall recesses. In some embodiments, the sidewalls of the semiconductor layers 104, 105, and 204 may be etched using isotropic etching processes, such as wet etching or the like. In some embodiments where the semiconductor layers 104, 105, and 204 include, e.g., SiGe, and the semiconductor layers 102 and 202 include, e.g., Si, an etch process with tetramethylammonium hydroxide (TMAH), ammonium hydroxide (NH₄OH), or the like may be used to etch sidewalls of the semiconductor layers 104, 105, and 204.

Then, inner spacers 116 are formed in the sidewall recesses on opposite ends of each of the semiconductor layers 104, 105, and 204. In some embodiments, the inner spacers 116 may be formed by, for example, depositing an inner spacer layer blanket over the substrate 100 and filling the sidewall recesses, and then performing an anisotropic etching to remove portions of the inner spacer layer outside the sidewall recesses, leaving the remaining portions of the inner spacer layer in the sidewall recesses as the inner spacers 116. The inner spacers 116 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

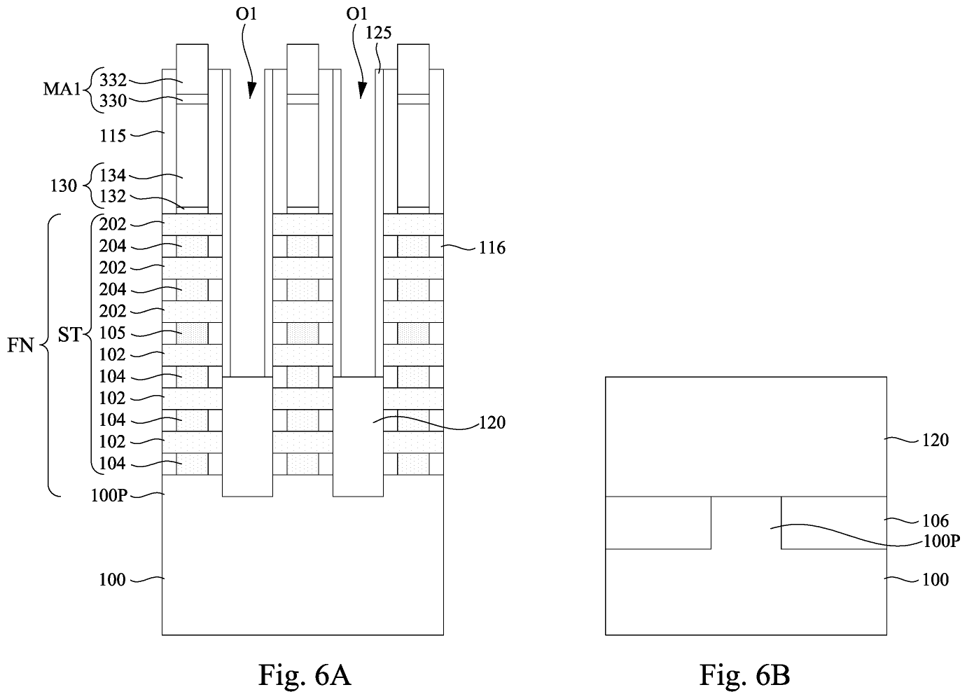

Reference is made to FIGS. 6A and 6B. Dummy materials 120 are formed in the source/drain openings O1. In greater detail, the dummy materials 120 may be formed at lower portions of the source/drain openings O1, such that the top surfaces of the dummy materials 120 may be lower than the bottommost semiconductor layer 202. As a result, the sidewalls of the semiconductor layers 202 may be exposed through the upper portions of the source/drain openings O1 once the dummy materials 120 are formed. In some embodiments, the dummy materials 120 may be formed by, for example, depositing a dielectric material filling the source/drain openings O1, and then etching back the dielectric material to lower the top surface of the dielectric material to a desired position. In some embodiments, the dummy materials 120 may be made of SiOCN, or other suitable material.

Afterwards, liners 125 are formed lining sidewalls of the upper portions of the source/drain openings O1, so as to cover the sidewall surfaces of the semiconductor layers 202. The liners 125 may also cover the sidewalls of the gate spacers 115. In some embodiments, the liners 125 may be formed by, for example, depositing a liner layer blanket over the substrate, an anisotropic etching process is performed to remove horizontal portions of the liner layer, such that vertical portions of the liner layer remain on sidewalls of the semiconductor layers 202 and the gate spacers 115. In some embodiments, the remaining vertical portions can be referred to as the liners 125. In some embodiments, the liners 125 may be made of SiN, metal oxide, or other suitable material.

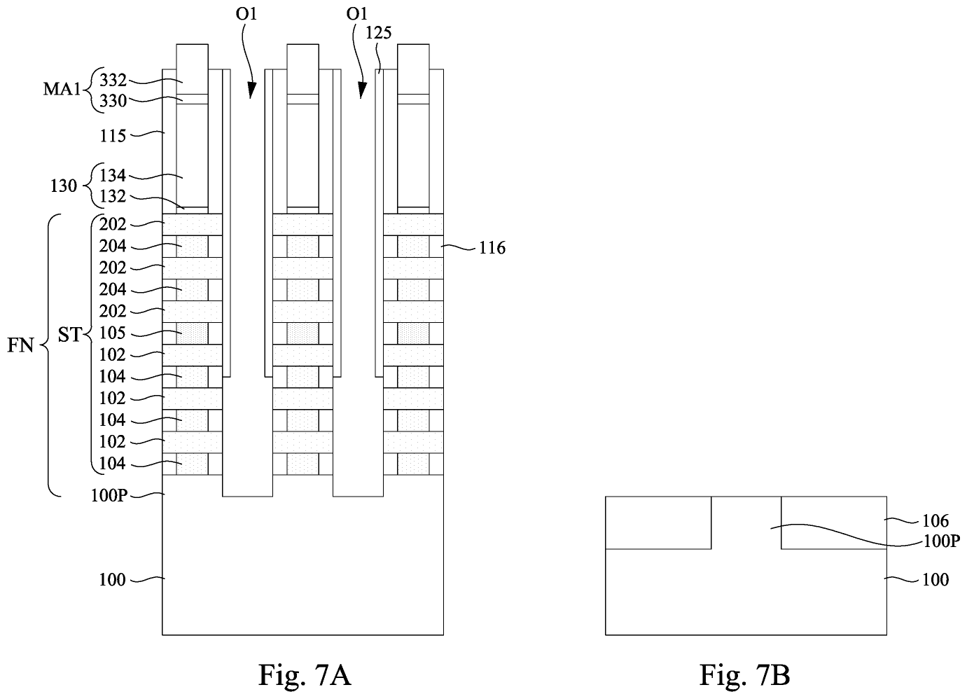

Reference is made to FIGS. 7A and 7B. The dummy materials 120 are removed by suitable etching process, so as to expose the sidewalls of the semiconductor layers 102 through the lower portions of the source/drain openings O1. In some embodiments, the liners 125 may include a higher etching resistance to the etching process than the dummy materials 120, and thus the liners 125 may remain after the dummy materials 120 are removed.

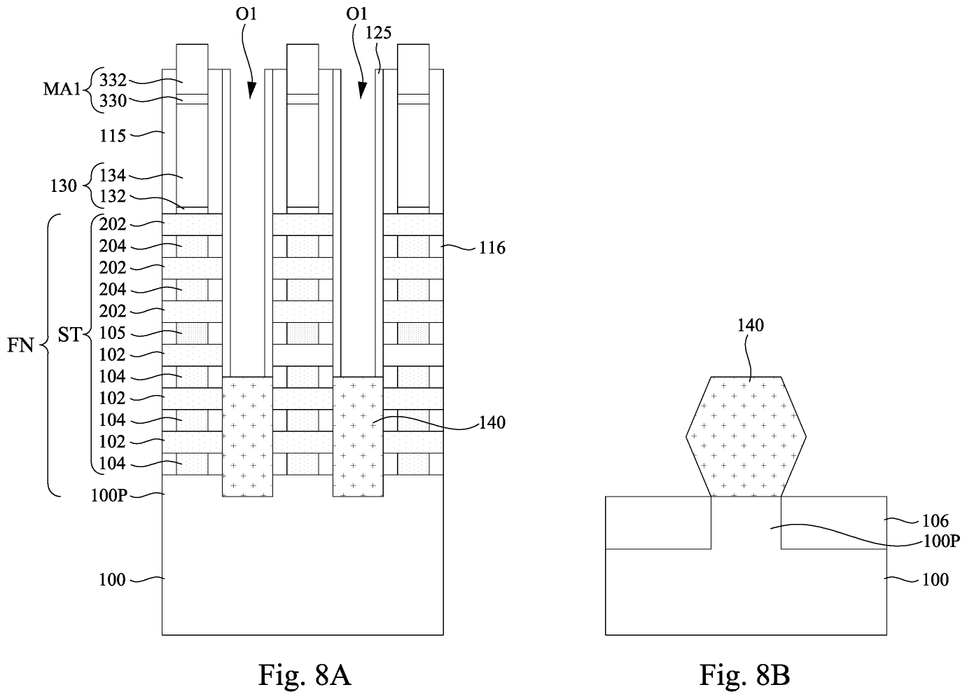

Reference is made to FIGS. 8A and 8B. First source/drain epitaxy structures 140 are formed on opposite ends of each of the semiconductor layers 102. In some embodiments, the first source/drain epitaxy structures 140 may be formed by a selective epitaxial growth (SEG) process. The SEG process may selectively grow a semiconductor material on exposed semiconductor surfaces, such as the exposed surfaces of the semiconductor layers 102 and the exposed surface of the semiconductor strip 100P. On the other hand, the SEG process would not grow a semiconductor material from surfaces of the semiconductor layers 202, because the surfaces of the semiconductor layers 202 are covered by the liners 125. In some embodiments, the first source/drain epitaxy structures 140 may be doped with p-type dopants, such as boron (B), gallium (Ga), indium (In), aluminium (Al), or the like.

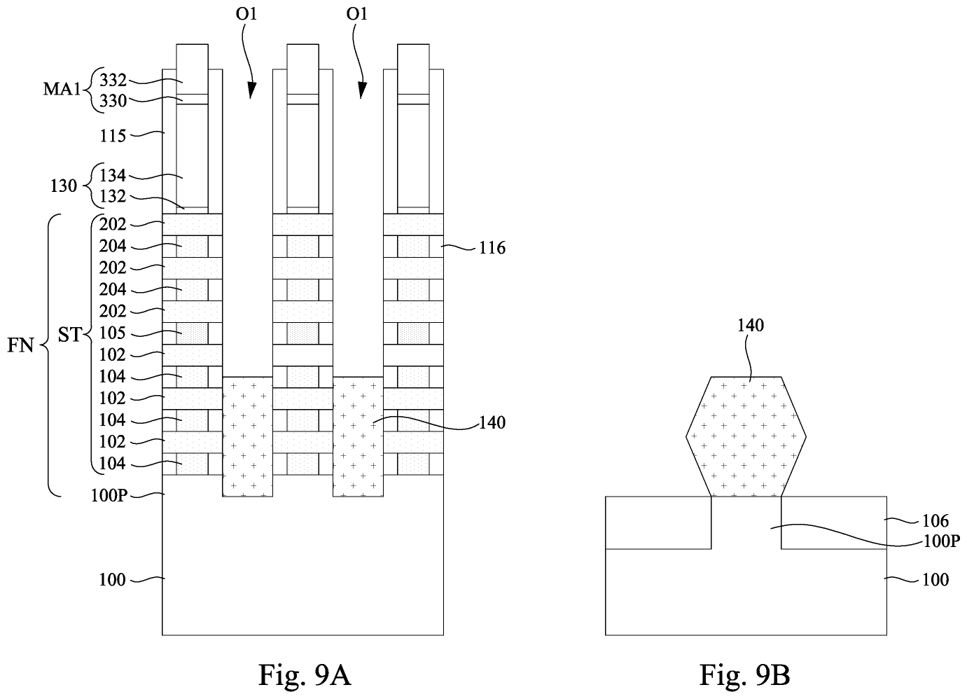

Reference is made to FIGS. 9A and 9B. After the first source/drain epitaxy structures 140 are formed, the liners 125 are removed through suitable etching process. After the liners 125 are removed, the sidewalls of the semiconductor layers 202 are exposed.

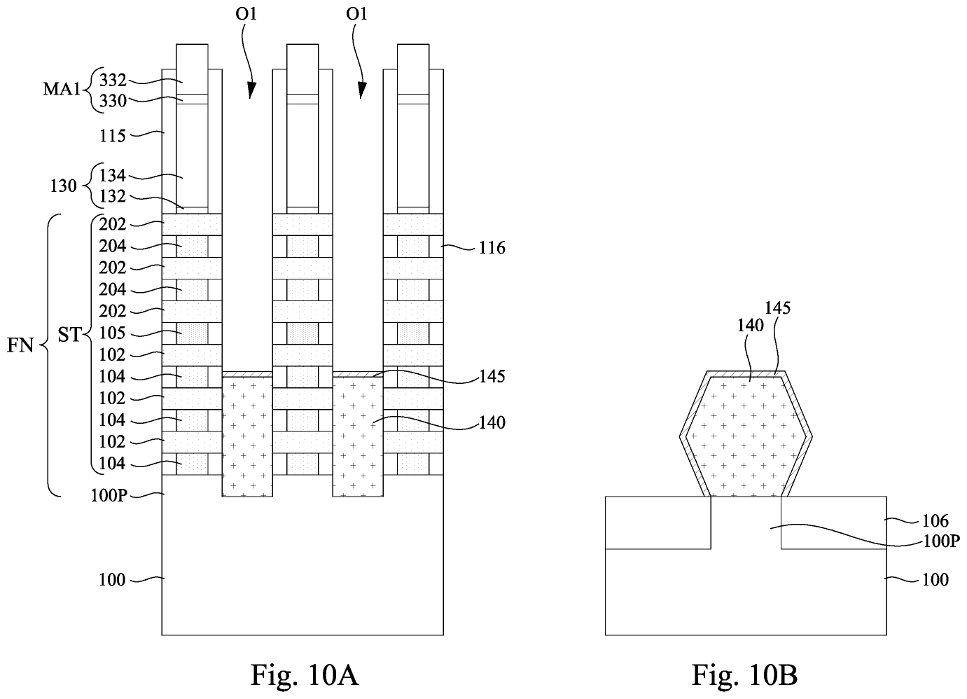

Reference is made to FIGS. 10A and 10B. First metal silicide layers 145 are formed on the exposed surfaces of the first source/drain epitaxy structures 140. In greater detail, the first metal silicide layers 145 are formed selectively on the exposed surfaces of the first source/drain epitaxy structures 140. For example, the first metal silicide layers 145 may be formed by, for example, depositing a metal layer into the source/drain openings O1, and then performing an annealing process so that portions of the metal layer may react with the first source/drain epitaxy structures 140 to form the first metal silicide layers 145. In some embodiments, the un-reacted portions of the metal layer may then be removed using suitable etching process. In some embodiments, the first metal silicide layers 145 may include molybdenum silicide (MoSi₂), tungsten silicide (WSi₂), tantalum silicide (TaSi₂), or other suitable silicide.

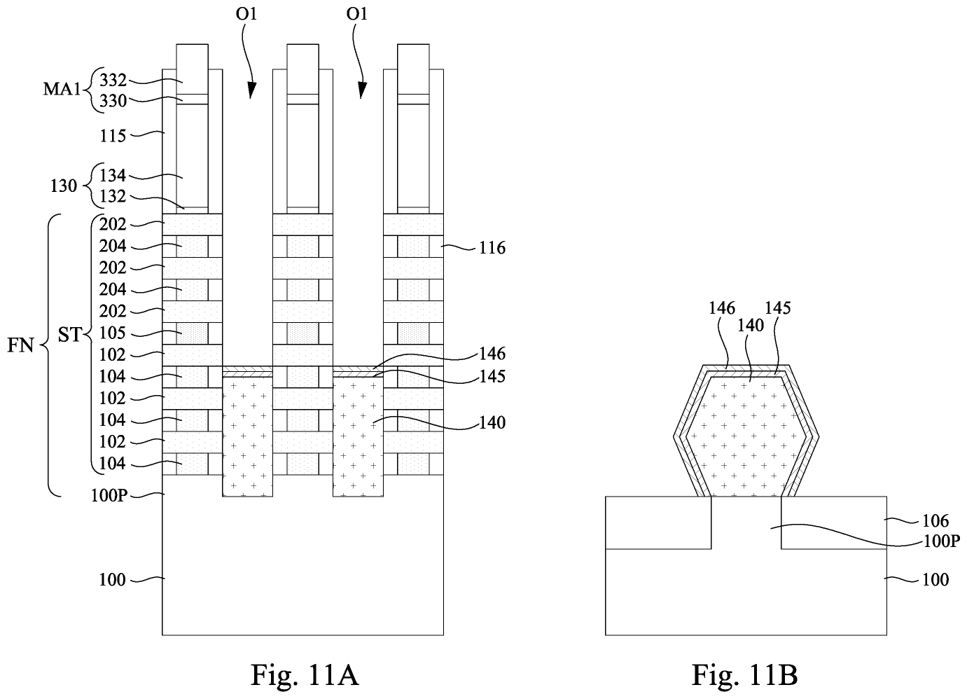

Reference is made to FIGS. 11A and 11B. Metal caps 146 are formed over the first metal silicide layers 145. In greater detail, the metal caps 146 are formed selectively on the exposed surfaces of the first metal silicide layers 145. For example, the metal caps 146 can be formed using an electro-plating like process, such that metal material of the metal caps 146 tends to form on a metal-containing surface, such as the first metal silicide layers 145.

In some embodiments, the metal caps 146 may include metal that is the same as the metal element of the first metal silicide layers 145. For example, if the first metal silicide layers 145 are made of molybdenum silicide (MoSi₂), the metal caps 146 may be made of molybdenum (Mo). If the first metal silicide layers 145 are made of tungsten silicide (WSi₂), the metal caps 146 may be made of tungsten (W). If the first metal silicide layers 145 are made of tantalum silicide (TaSi₂), the metal caps 146 may be made of tantalum (Ta).

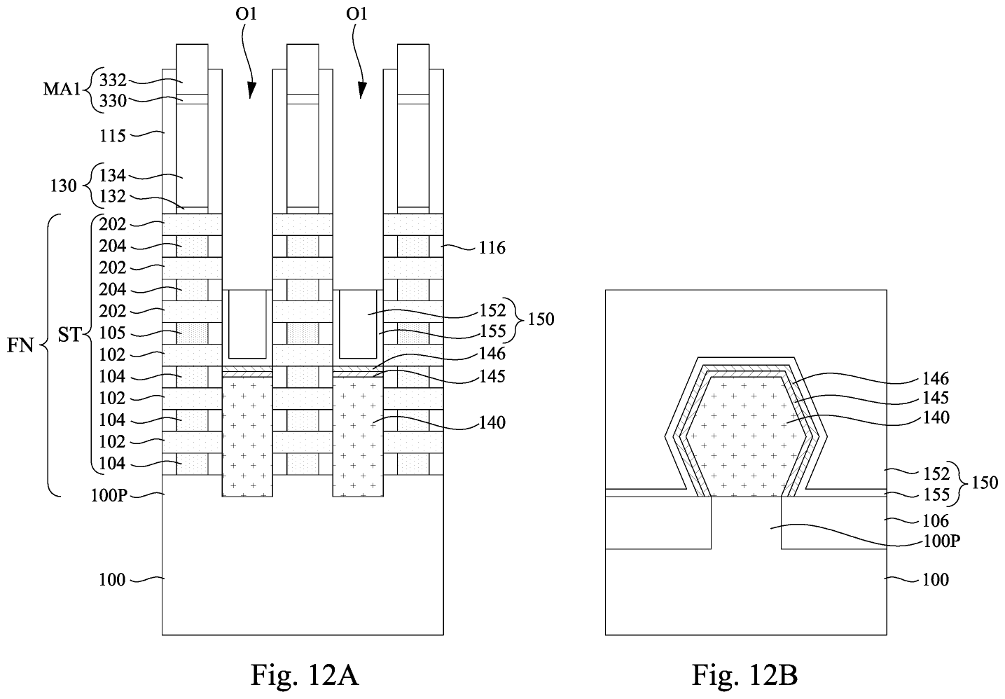

Reference is made to FIGS. 12A and 12B. A contact etch stop layer (CESL) 155 is formed covering the metal caps 146, the first metal silicide layers 145, and the first source/drain epitaxy structures 140. Afterwards, an interlayer dielectric (ILD) layer 152 is formed over the CESL 155. Then, an etching back process is performed to lower top surfaces of the CESL 155 and the ILD layer 152 to a position, such that at least parts of the semiconductor layers 202 are exposed through the source/drain openings O1. In some embodiments, the CESL 155 and the ILD layer 152 can be collectively referred to as an isolation structure 150. As shown in FIG. 12B, the isolation structure 150 laterally surrounds the first source/drain epitaxy structure 140.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

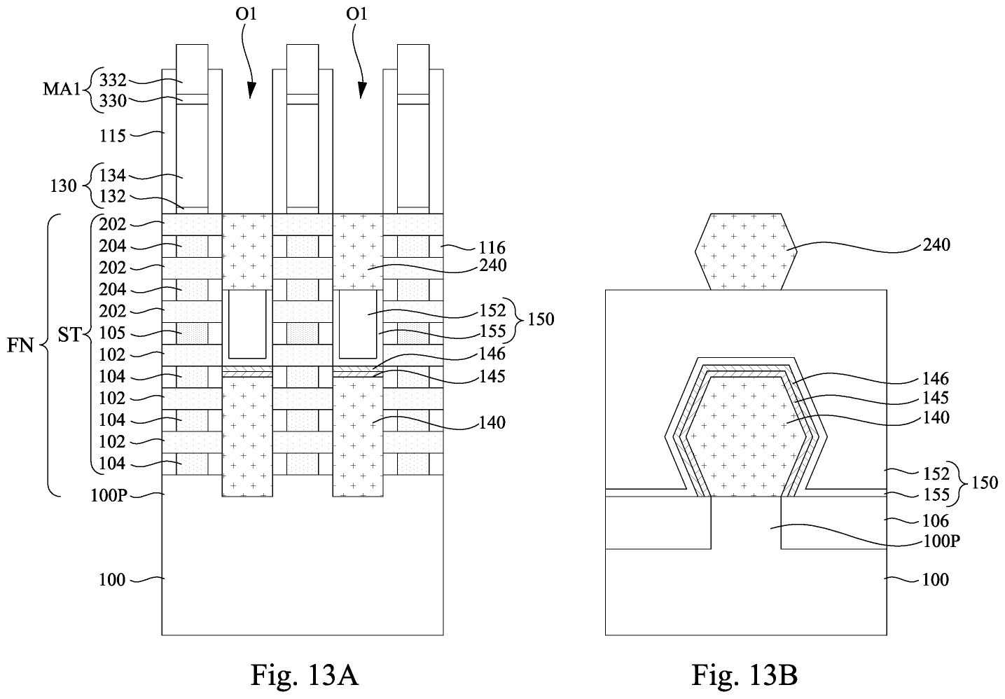

Reference is made to FIGS. 13A and 13B. Second source/drain epitaxy structures 240 are formed on opposite ends of each of the semiconductor layers 202. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the semiconductor layers 202. In some embodiments, the second source/drain epitaxy structures 240 may be doped with n-type dopants, such as phosphorus (P), arsenic (As), or antimony (Sb), or the like.

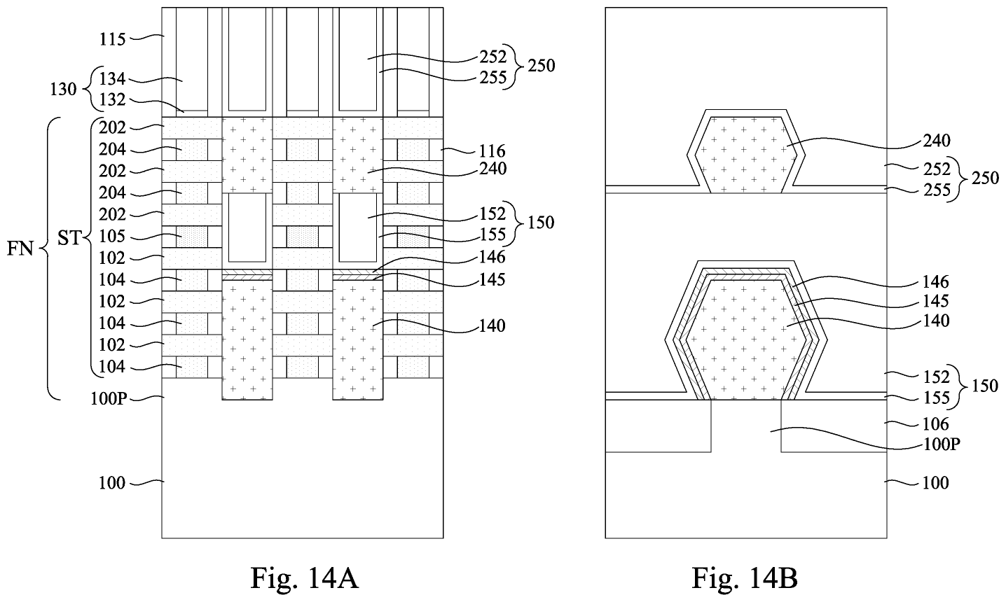

Reference is made to FIGS. 14A and 14B. A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 130 are exposed. In some embodiments, the patterned masks MA1 are removed during the planarization process. In some embodiments, the CESL 255 and the ILD layer 252 can be collectively referred to as an isolation structure 250. As shown in FIG. 14B, the isolation structure 250 laterally surrounds the second source/drain epitaxy structure 240. The materials of the CESL 255 and the ILD layer 252 may be similar to the materials of the CESL 155 and the ILD layer 152, respectively, and thus relevant details will not be repeated for brevity. In some embodiments, the isolation structures 150 and 250 can be collectively referred to as an isolation structure.

As shown in the cross-sectional view of FIG. 14B, because the first metal silicide layer 145 and the metal cap 146 are formed on the exposed surface of the first source/drain epitaxy structure 140 prior to forming the isolation structure 150, the surface of the first source/drain epitaxy structure 140 may be separated from the isolation structure 150 through the first metal silicide layer 145 and the metal cap 146. On the other hand, because no metal silicide layer and metal cap are formed on the second source/drain epitaxy structure 240 prior to forming the isolation structure 250, surface of the second source/drain epitaxy structure 240 may be in contact with the isolation structure 250. For example, the surfaces of the second source/drain epitaxy structures 240 are in contact with the CESL 255.

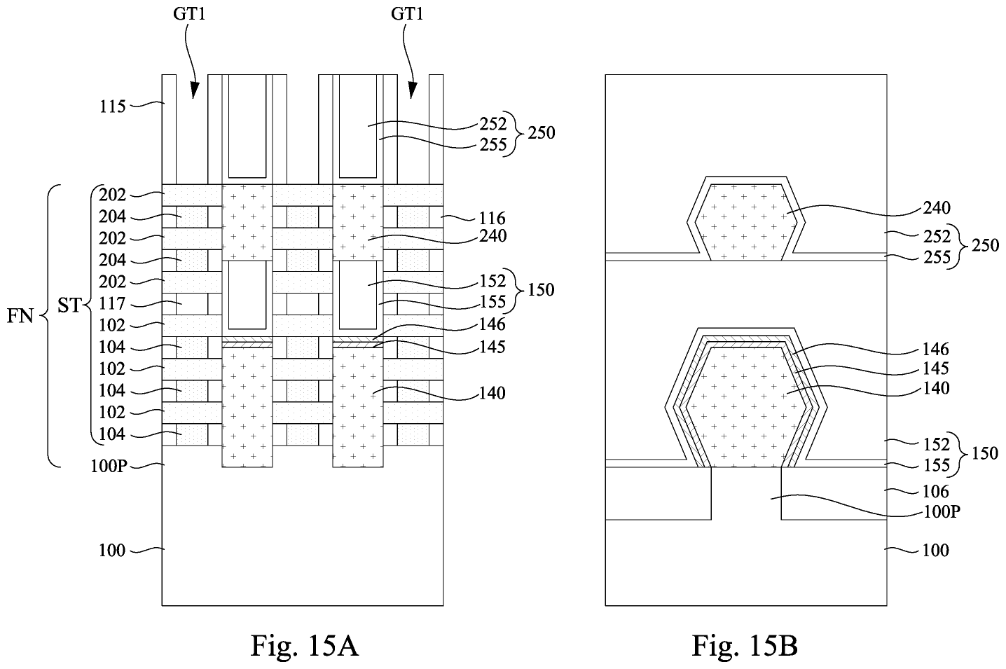

Reference is made to FIGS. 15A and 15B. The dummy gate structures 130 are removed to form gate trenches GT1 between each pair of the gate spacers 115. Then, the semiconductor layer 105 is replaced with an isolation layer 117. For example, an etching process is performed to remove the semiconductor layer 105 to form a gap vertically between the topmost semiconductor layer 102 and the bottommost semiconductor layer 202. As mentioned above, because the semiconductor layer 105 has a higher germanium concentration than the semiconductor layers 102, 104, 202, and 204, the etchant can be properly selected such that the semiconductor layer 105 is selectively removed, while keeping the semiconductor layers 102, 104, 202, and 204 substantially intact.

Afterwards, isolation material is formed in the gate trench GT1 and filling the gap. An anisotropic etching process is performed to remove the isolation material outside the gap, and the remaining portion of the isolation material in the gap is referred to as the isolation layer 117. The material of the isolation layer 117 may be similar to the inner spacers 116, and thus relevant details will not be repeated for brevity.

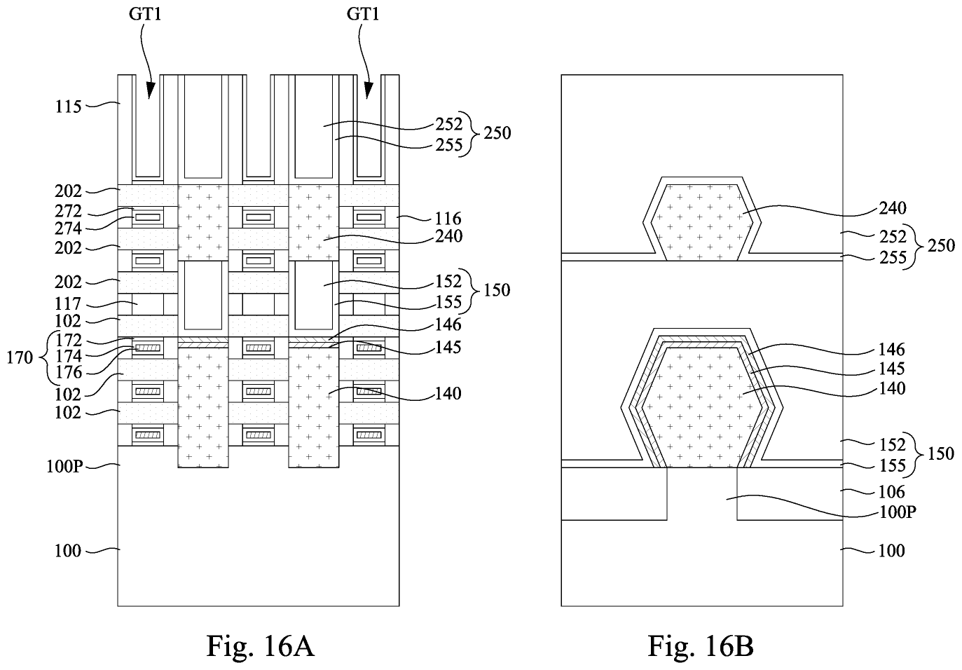

Reference is made to FIGS. 16A and 16B. After the isolation layer 117 is formed, an etching process is performed to remove the semiconductor layers 104 and 204 through the gate trenches GT1, such that that the semiconductor layers 102 and 202 are suspended over the substrate 100.

Afterwards, interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 are formed in the gate trenches GT1 and over the gate dielectric layers 174. The gate electrodes 176 are then etched back, such that the remaining gate electrodes 176 are at the lower portion of the gate trenches GT1. Accordingly, first metal gate structures 170 are formed. In greater detail, the first metal gate structures 170 are formed in bottom portions of the gate trenches GT1, such that the first metal gate structures 170 may wrap around the respective semiconductor layers 102. In some embodiments, each of the first metal gate structures 170 may include the interfacial layer 172, the gate dielectric layer 174 over the interfacial layer 172, and the gate electrode 176 over the gate dielectric layer 174.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

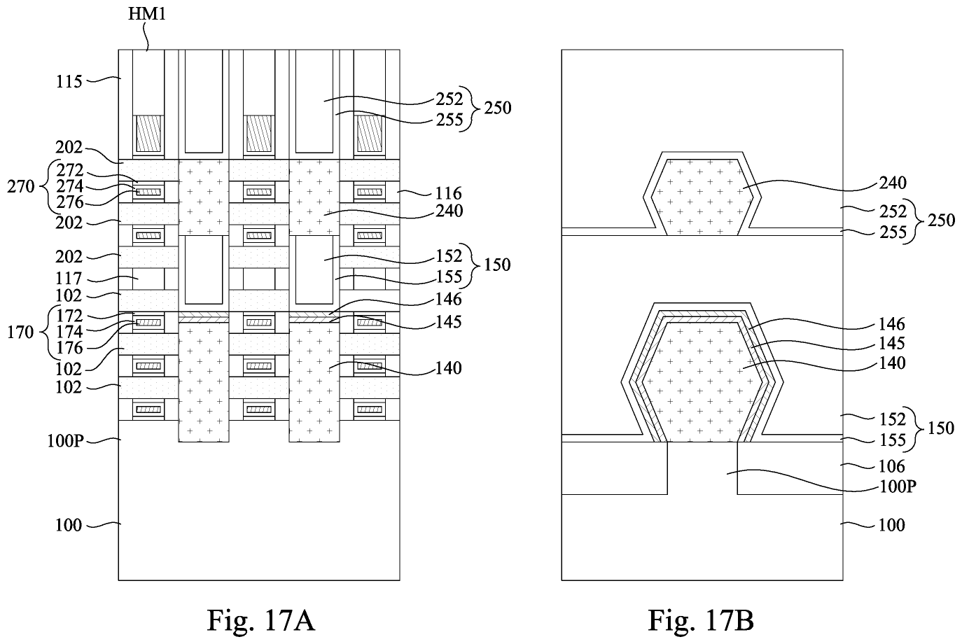

Reference is made to FIGS. 17A and 17B. Gate electrodes 276 are formed in the gate trenches GT1 and over the first metal gate structures 170. Accordingly, second metal gate structures 270 are formed. In greater detail, the second metal gate structures 270 are formed in upper portions of the gate trenches GT1 and above the first metal gate structures 170, such that the second metal gate structures 270 may wrap around the respective semiconductor layers 202. In some embodiments, each of the second metal gate structures 270 may include the interfacial layer 272, the gate dielectric layer 274 over the interfacial layer 272, and the gate electrode 276 over the gate dielectric layer 274. The materials of the gate electrode 276 may be similar to those described with respect to the gate electrode 176, and thus relevant details will not be repeated for brevity.

The second metal gate structures 270 are then etched back, such that top surfaces of the second metal gate structures 270 are lower than top surfaces of the gate spacers 115. Afterwards, hard masks HM1 are formed over respectively second metal gate structures 270. In some embodiments, the hard masks HM1 may include one or more layers of insulating material such as silicon nitride based material including SiN, SiCN and SiOCN.

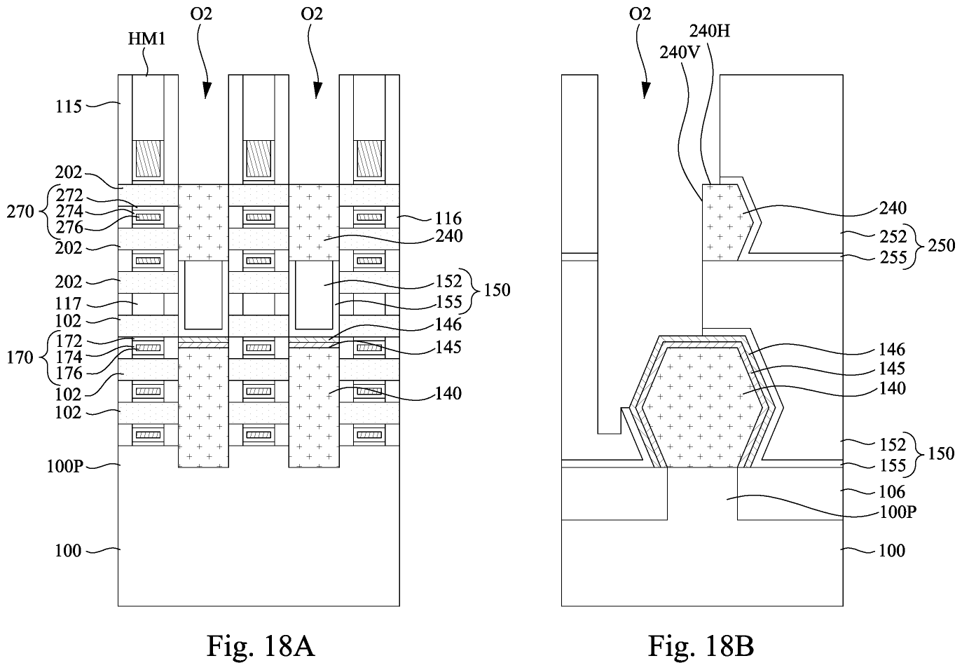

Reference is made to FIGS. 18A and 18B. The isolation structures 150 and 250 are etched to form contact openings O2. In some embodiments, a patterned mask (not shown) may be formed over the substrate 100, in which the patterned mask may include openings that expose the isolation structures 250. The etching process is performed to remove portions of the isolation structures 150 and 250 through the openings of the patterned mask, so as to form the contact openings O2. After the etching process is completed, the patterned mask is removed.

Referring to the cross-sectional view of FIG. 18B, as mentioned above, because there is no metal silicide layer covering the second source/drain epitaxy structure 240, the second source/drain epitaxy structure 240 may also be etched during etching the isolation structures 150 and 250. For example, in FIG. 18B, a portion of the second source/drain epitaxy structure 240 exposed through the contact openings O2 is removed. As a result, the second source/drain epitaxy structure 240 may include an asymmetric cross-sectional profile. However, because the first metal silicide layer 145 and the metal cap 146 are formed over the first source/drain epitaxy structure 140, the first metal silicide layer 145 and the metal cap 146 can act as etch stop layer to prevent the first source/drain epitaxy structure 140 from the etching process. As a result, the first source/drain epitaxy structure 140 may include a substantially symmetric cross-sectional profile. From another aspect, in the cross-sectional view of FIG. 18B, the first source/drain epitaxy structure 140 may include a more symmetric cross-sectional profile than the second source/drain epitaxy structure 240. In some embodiments, the widest width of the second source/drain epitaxy structure 240 may be less than the widest width of the first source/drain epitaxy structure 140. Moreover, the etched second source/drain epitaxy structure 240 may include a vertical surface 240V and a horizontal surface 240H that are exposed to the contact opening O2.

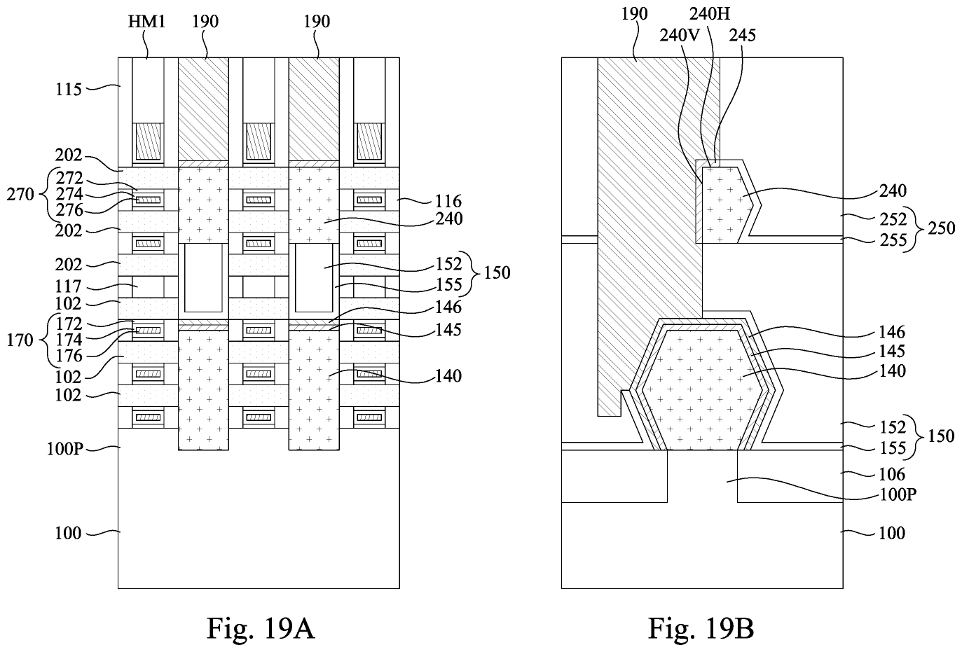

Reference is made to FIGS. 19A and 19B. Second metal silicide layers 245 are formed on the exposed surfaces of the second source/drain epitaxy structures 240. In greater detail, the second metal silicide layers 245 are formed selectively on the exposed surfaces of the second source/drain epitaxy structures 240. For example, the second metal silicide layers 245 may be formed by, for example, depositing a metal layer into the contact openings O2, and then performing an annealing process so that portion of the metal layer may react with the exposed surfaces of the second source/drain epitaxy structures 240. In some embodiments, the un-reacted portions of the metal layer may then be removed using suitable etching process.

In some embodiments, the second metal silicide layers 245 may include a different metal element than the first metal silicide layers 145. For example, the second metal silicide layers 245 may include titanium (Ti), such as titanium silicide (TiSi) or titanium disilicide (TiSi₂).

In some embodiments, prior to forming the second metal silicide layers 245, a high selective isotropic pre-clean process may be performed to remove native oxide on exposed surfaces of the second source/drain epitaxy structures 240. Moreover, a plasma doping may be performed during forming the second metal silicide layers 245. In some embodiments, the second metal silicide layers 245 may be n-doped TiSi₂.

In some embodiments, the first metal silicide layers 145 are formed prior to forming the metal gate structures 170 and 270, and thus the formation of the first metal silicide layers 145 can be referred to as a “silicide first” process. On the contrary, the second metal silicide layers 245 are formed after forming the metal gate structures 170 and 270, and thus the formation of the second metal silicide layers 245 can be referred to as a “silicide last” process.

Referring to the cross-sectional view of FIG. 19B, the second metal silicide layer 245 is in contact with a first portion of the second source/drain epitaxy structure 240. In greater detail, the second metal silicide layer 245 is formed on the vertical surface 240V and the horizontal surface 240H of the second source/drain epitaxy structure 240. In some embodiments, a second portion of the second source/drain epitaxy structure 240 is protected by the isolation structure 250 during forming the contact opening O2, and thus the second portion of the second source/drain epitaxy structure 240 is in contact with the isolation structures 150 and 250. On the other hand, a first portion of the first source/drain epitaxy structure 140 is in contact with the first metal silicide layer 145, and a second portion of the first source/drain epitaxy structure 140 is in contact with the semiconductor strip 100P. In the cross-sectional view of FIG. 19B, a portion of the second source/drain epitaxy structure 240 is in contact with a dielectric material (e.g., isolation structures 150 and 250), while an entirety of the first source/drain epitaxy structure 140 may be free of coverage by a dielectric material.

After the second metal silicide layers 245 are formed, contact plugs 190 are formed in the contact openings O2. In the cross-sectional view of FIG. 19B, the contact plug 190 may be in contact with the second metal silicide layer 245 and the metal cap 246. The contact plug 190 may be separated from the first metal silicide layer 145 through the metal cap 246. In some embodiments, the contact plugs 190 may be formed by, for example, depositing a conductive material in the contact openings O2, and then performing a planarization process (e.g., CMP) until the isolation structure 250 is exposed. In some embodiments, the conductive material may include one or more layers of Co, Ni, W, Ti, Ta, Cu, Al, TiN, and TaN, combinations thereof, and/or other suitable material. In some embodiments, each contact plug 190 may electrically connects the first source/drain epitaxy structure 140 and the overlying second source/drain epitaxy structure 240.

In the embodiments of the present disclosure, a CFET 10 is provided, the CFET 10 may include a first transistor TR1 and a second transistor TR2 over the first transistor TR2. According to the above discussed processes, the first metal silicide layers 145 are formed through a “silicide-first” process. The “silicide-first” process may ensure a larger contact area between the first metal silicide layers 145 and the corresponding first source/drain epitaxy structures 140. Because the landing region of the contact plugs 190 may be small for the bottom first transistor TR1, the enlarged contact area between the first metal silicide layers 145 and the corresponding first source/drain epitaxy structures 140 may reduce the contact resistance at the first source/drain epitaxy structures 140, and will further improve the device performance. Moreover, metal caps 146 may be formed over the first metal silicide layers 145 and can act as protection layers to prevent the first metal silicide layers 145 from oxidation or damage during the following manufacturing process.

The first metal silicide layers 145 may also include thermally stable materials, such as molybdenum silicide (MoSi₂), tungsten silicide (WSi₂), tantalum silicide (TaSi₂). The melting point of the material of the first metal silicide layers 145 may be greater than about 2000° C. For example, the melting points of MoSi₂, WSi₂, and TaSi₂ are 2030° C., 2165° C., and 2200° C., respectively. In some embodiments, the material of the first metal silicide layers 145 may include higher melting point than the material of the second metal silicide layers 245. For example, the second metal silicide layers 245 may include titanium silicide (TiSi) or titanium disilicide (TiSi₂), and the melting points of TiSi and TiSi₂ are 1840° C. and 1750° C., respectively. Because the first metal silicide layers 145 are formed through a “silicide-first” process, material with higher melting point may increase the capability for sustaining high temperature during the manufacturing processes.

Because the first transistor TR1 may be a p-type transistor, and the second transistor TR2 may be an n-type transistor, the first metal silicide layers 145 may also include material that is suitable for p-type device. In some embodiments, the material of the first metal silicide layers 145 may include a lower p-SBH (p-Schottky barrier height) such as WSi₂ (0.44 eV), MoSi₂ (0.52 eV) than the material of the second metal silicide layers such TiSi₂ (0.62 eV) in 245. Here, the “p-SBH” may be referred to as the potential difference between the valence band edge Eᵥ and the fermi level E_{F} at a junction between the material and an un-doped silicon.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a CFET, which includes a first transistor and a second transistor above the first transistor. A “silicide-first” process is performed to form first metal silicide layers on the first source/drain epitaxy structures, which will result in a larger contact area between the first metal silicide layers and the corresponding first source/drain epitaxy structures. Accordingly, the effective conductive area between the first source/drain epitaxy structure and a contact plug may be enlarged, and thus the resistance between the first source/drain epitaxy structure and the contact plug may be reduced, and will further improve the device performance. The first metal silicide layers may include a thermally stable material, which is beneficial to sustain the high temperature during the manufacturing processes.

In some embodiments of the present disclosure, a semiconductor device includes a first transistor, a second transistor vertically above the first transistor, a first metal silicide layer, a second metal silicide layer, and an isolation structure. The first transistor includes a first channel layer, a first gate structure over the first channel layer, and first source/drain epitaxy structures on opposite ends of the first channel layer. The second transistor includes a second channel layer, a second gate structure over the second channel layer, and second source/drain epitaxy structures on opposite ends of the second channel layer. The first metal silicide layer is over one of the first source/drain epitaxy structures. The second metal silicide layer is over one of the second source/drain epitaxy structures. The isolation structure covers the one of the first source/drain epitaxy structures and the one of the second source/drain epitaxy structures, wherein in a cross-sectional view, the one of the first source/drain epitaxy structures is separated from the isolation structure through the first metal silicide layer, while the one of the second source/drain epitaxy structures is in contact with the isolation structure.

In some embodiments, a material of the first metal silicide layer is different from a material of the second metal silicide layer.

In some embodiments, a material of the first metal silicide layer has a higher melting point than a material of the second metal silicide layer.

In some embodiments, the semiconductor device further includes a metal cap over the first metal silicide layer, wherein the metal cap is between the first metal silicide layer and the isolation structure.

In some embodiments, the semiconductor device further includes a contact plug in contact with the second metal silicide layer and the metal cap, wherein the contact plug is separated from the first metal silicide layer through the metal cap.

In some embodiments, the first metal silicide layer and the metal cap comprise a same metal element.

In some embodiments, in the cross-sectional view, a widest width of the one of the first source/drain epitaxy structures is greater than a widest width of the one of the second source/drain epitaxy structures.

In some embodiments of the present disclosure, a semiconductor device includes a first transistor, a second transistor vertically above the first transistor, a first metal silicide layer, and a second metal silicide layer. The first transistor includes a first channel layer, a first gate structure over the first channel layer, and first source/drain epitaxy structures on opposite ends of the first channel layer. The second transistor includes a second channel layer, a second gate structure over the second channel layer, and second source/drain epitaxy structures on opposite ends of the second channel layer. The first metal silicide layer is over one of the first source/drain epitaxy structures. The second metal silicide layer is over one of the second source/drain epitaxy structures, wherein a material of the first metal silicide layer is different from a material of the second metal silicide layer, and the material of the first metal silicide layer has a higher melting point than the material of the second metal silicide layer.

In some embodiments, in a cross-sectional view, the one of the first metal silicide layer has a more symmetric cross-sectional profile than the one of the second metal silicide layer.

In some embodiments, the semiconductor device further includes a metal cap over the first metal silicide layer.

In some embodiments, the semiconductor device further includes a contact plug in contact with the metal cap and the second metal silicide layer.

In some embodiments, the semiconductor device further includes a first isolation structure and a second isolation structure. The first isolation structure laterally surrounds the one of the first source/drain epitaxy structures, wherein the one of the first source/drain epitaxy structures is separated from the first isolation structure. The second isolation structure laterally surrounds the one of the second source/drain epitaxy structures, wherein the one of the second source/drain epitaxy structures is in contact with the second isolation structure.

In some embodiments, in a cross-sectional view, the one of the first metal silicide layer is free of coverage by a dielectric material.

In some embodiments, a material of the first metal silicide layer comprises a lower p-Schottky barrier height than a material of the second metal silicide layer.

In some embodiments, the first metal silicide layer comprises molybdenum silicide, tungsten silicide, or tantalum silicide, and the second metal silicide layer comprises titanium silicide.

In some embodiments of the present disclosure, a method includes forming a first stack of alternating first channel layers and first sacrificial layers over a substrate; forming a second stack of alternating second channel layers and second sacrificial layers over the first stack; forming first source/drain epitaxy structures on opposite ends of each of the first channel layers; forming first metal silicide layers over the first source/drain epitaxy structures, respectively; after the first metal silicide layers are formed, forming second source/drain epitaxy structures on opposite ends of each of the second channel layers; removing the first sacrificial layers and the second sacrificial layers; forming a first gate structure wrapping around each of the first channel layers and a second gate structure wrapping around each of the second channel layers; and after the first and second gate structures are formed, forming second metal silicide layers over the second source/drain epitaxy structures, respectively.

In some embodiments, the method further includes forming a first isolation structure over the first metal silicide layers; forming a second isolation structure over and in contact with the second source/drain epitaxy structures; and etching the first isolation structure and the second isolation structure to form contact openings, wherein the second metal silicide layers are formed over the second source/drain epitaxy structures through the contact openings.

In some embodiments, the method further includes forming metal caps over and in contact with the first metal silicide layers, wherein the contact openings expose the metal caps.

In some embodiments, etching the first isolation structure and the second isolation structure to form the contact openings is performed such that portions of the second source/drain epitaxy structures are removed, while the first source/drain epitaxy structures are protected by the first metal silicide layers during etching the first isolation structure and the second isolation structure.

In some embodiments, a material of the first metal silicide layers has a higher melting point than a material of the second metal silicide layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor, comprising:
a first channel layer;
a first gate structure over the first channel layer; and
first source/drain epitaxy structures on opposite ends of the first channel layer;
a second transistor vertically above the first transistor, comprising:
a second channel layer;
a second gate structure over the second channel layer; and
second source/drain epitaxy structures on opposite ends of the second channel layer;
a first metal silicide layer over one of the first source/drain epitaxy structures;
a second metal silicide layer over one of the second source/drain epitaxy structures; and
an isolation structure covering the one of the first source/drain epitaxy structures and the one of the second source/drain epitaxy structures, wherein in a cross-sectional view, the one of the first source/drain epitaxy structures is separated from the isolation structure through the first metal silicide layer, while the one of the second source/drain epitaxy structures is in contact with the isolation structure.

2. The semiconductor device of claim 1, wherein a material of the first metal silicide layer is different from a material of the second metal silicide layer.

3. The semiconductor device of claim 2, wherein a material of the first metal silicide layer has a higher melting point than a material of the second metal silicide layer.

4. The semiconductor device of claim 1, further comprising a metal cap over the first metal silicide layer, wherein the metal cap is between the first metal silicide layer and the isolation structure.

5. The semiconductor device of claim 4, further comprising a contact plug in contact with the second metal silicide layer and the metal cap, wherein the contact plug is separated from the first metal silicide layer through the metal cap.

6. The semiconductor device of claim 4, wherein the first metal silicide layer and the metal cap comprise a same metal element.

7. The semiconductor device of claim 1, wherein in the cross-sectional view, a widest width of the one of the first source/drain epitaxy structures is greater than a widest width of the one of the second source/drain epitaxy structures.

8. A semiconductor device, comprising:
a first transistor, comprising:
a first channel layer;
a first gate structure over the first channel layer; and
first source/drain epitaxy structures on opposite ends of the first channel layer;
a second transistor vertically above the first transistor, comprising:
a second channel layer;
a second gate structure over the second channel layer; and
second source/drain epitaxy structures on opposite ends of the second channel layer;
a first metal silicide layer over one of the first source/drain epitaxy structures; and
a second metal silicide layer over one of the second source/drain epitaxy structures, wherein a material of the first metal silicide layer is different from a material of the second metal silicide layer, and the material of the first metal silicide layer has a higher melting point than the material of the second metal silicide layer.

9. The semiconductor device of claim 8, wherein in a cross-sectional view, the one of the first metal silicide layer has a more symmetric cross-sectional profile than the one of the second metal silicide layer.

10. The semiconductor device of claim 8, further comprising a metal cap over the first metal silicide layer.

11. The semiconductor device of claim 10, further comprising a contact plug in contact with the metal cap and the second metal silicide layer.

12. The semiconductor device of claim 8, further comprising:
a first isolation structure laterally surrounding the one of the first source/drain epitaxy structures, wherein the one of the first source/drain epitaxy structures is separated from the first isolation structure; and
a second isolation structure laterally surrounding the one of the second source/drain epitaxy structures, wherein the one of the second source/drain epitaxy structures is in contact with the second isolation structure.

13. The semiconductor device of claim 8, wherein in a cross-sectional view, the one of the first metal silicide layer is free of coverage by a dielectric material.

14. The semiconductor device of claim 8, wherein a material of the first metal silicide layer comprises a lower p-Schottky barrier height than a material of the second metal silicide layer.

15. The semiconductor device of claim 8, wherein the first metal silicide layer comprises molybdenum silicide, tungsten silicide, or tantalum silicide, and the second metal silicide layer comprises titanium silicide.

16. A method, comprising:
forming a first stack of alternating first channel layers and first sacrificial layers over a substrate;
forming a second stack of alternating second channel layers and second sacrificial layers over the first stack;
forming first source/drain epitaxy structures on opposite ends of each of the first channel layers;
forming first metal silicide layers over the first source/drain epitaxy structures, respectively;
after the first metal silicide layers are formed, forming second source/drain epitaxy structures on opposite ends of each of the second channel layers;
removing the first sacrificial layers and the second sacrificial layers;
forming a first gate structure wrapping around each of the first channel layers and a second gate structure wrapping around each of the second channel layers; and
after the first and second gate structures are formed, forming second metal silicide layers over the second source/drain epitaxy structures, respectively.

17. The method of claim 16, further comprising:
forming a first isolation structure over the first metal silicide layers;
forming a second isolation structure over and in contact with the second source/drain epitaxy structures; and
etching the first isolation structure and the second isolation structure to form contact openings, wherein the second metal silicide layers are formed over the second source/drain epitaxy structures through the contact openings.

18. The method of claim 17, further comprising forming metal caps over and in contact with the first metal silicide layers, wherein the contact openings expose the metal caps.

19. The method of claim 17, wherein etching the first isolation structure and the second isolation structure to form the contact openings is performed such that portions of the second source/drain epitaxy structures are removed, while the first source/drain epitaxy structures are protected by the first metal silicide layers during etching the first isolation structure and the second isolation structure.

20. The method of claim 16, wherein a material of the first metal silicide layers has a higher melting point than a material of the second metal silicide layers.
